(19) United States
(12) Patent Application Publication
(10) Pub. No.: US 2003/0025187 A1
(43) Pub. Date: Feb. 6, 2003

(54) Protective device for subassemblies

(76) Inventors: Volker Strutz, Tegernheim (DE); Uta Gebauer, Munchen (DE); Thorsten Meyer, Erlangen (DE)

Correspondence Address: LERNER AND GREENBERG, P.A., POST OFFICE BOX 2480, HOLLYWOOD, FL, 33022-2480, US

(21) Appl. No.: 10/210,603

(22) Filed: Aug. 1, 2002

(30) Foreign Application Priority Data
Aug. 1, 2001 (DE) 101 37 618.9

(51) Int. Cl. H01L 23/06; H01L 23/34; H01L 21/302; H01L 21/461

(52) U.S. Cl. 257/684; 257/725; 438/726

(57) ABSTRACT

A protective device is described for subassemblies having a substrate and components disposed thereon and to be protected, for example semiconductor components. The protective device has at least one covering element for covering a subassembly, and at least one compression prevention element, which is disposed between the at least one covering element and the substrate and which is connected to the substrate and a surface of the covering element which faces the components and the substrate in such a way that a predefined spacing between covering element and the components to be protected can be maintained or is maintained.

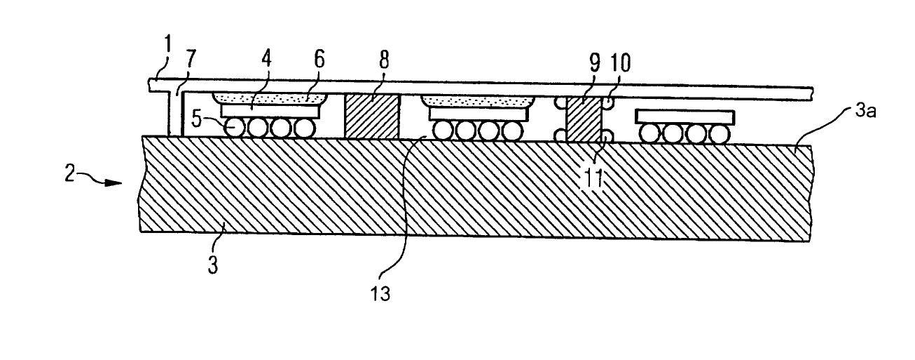

### BACKGROUND OF THE INVENTION

Field of the Invention

The present invention relates to a protective device for subassemblies, for example subassemblies having electronic components.

In the use of integrated semiconductor circuits, chips, as they are known, that is to say platelets based on silicon or gallium arsenite and cut out of a wafer with electric components produced photolithographically or by similar methods on its surface, the question of effective protection against mechanical and/or chemical influences is often posed. The question is often answered by introducing the chip into a housing, normally produced from plastic. However, a weak point in the chip mounting lies in the reaction of the electrical contacts between the chip and a substrate accommodating the chip, such as a circuit board, to the action of forces on the chip. In the event of displacement of the component or else in the event of direct action on the contact elements, the latter can be damaged. As a result of the use of housings, in this case the problem is merely displaced from the actual chip contacts (for example thin wires or contact elements similar to balls, ball grid arrays) to the contacts of the housing, even though the latter can normally be more highly loaded mechanically. In principle, however, there remains the problem that the contact elements have too low a resistance against forces acting on the component, for example the chip.

In recent times, for fabrication reasons and also for reasons concerned with space, economy and rationalization, use has increasingly been made of flip-chips, as they are known. These are integrated circuits that are fixed directly to the substrate, that is to say the circuit board, without a housing and contacted electrically. For this purpose, the individual chips still in the wafer composite are provided with suitable flexible contacts and, after the wafer has been cut up, are placed on the substrate with the contact side down. In order to permit testing of the flip-chips before they are used, customary test devices are used. In order to be able to use such test devices on the wafer, the contacts have to be configured to be sufficiently compliant that they are able to compensate for tilting between the surface of the wafer in the area of the flip-chip to be tested and the test device. However, after the flip-chip has been mounted on the substrate, this necessary compliance gives rise to corresponding mechanical sensitivity and leads to an increased need for protective measures.

A further development in recent times has been microcircuit boards, as they are known, in which a plurality of chips are applied to the microcircuit board substrate with the structured sides upward and are connected to the conductor track structures of the microcircuit boards by wire bonding. Here, too, protection of the chips and in particular of the contact wires as well against mechanical effects is desirable.

In the case of conventional fixing of a mechanical protective element such as a cover onto a substrate, such as is carried out by riveting for example, because of the tolerances of the substrate, the receiving holes for the rivets and the protective element, a movement of the protective element in the X and Y direction, that is to say parallel to the plane of the substrate, is possible even after mounting. However, in microelectronics it is generally usual and desirable continually to reduce the dimensions of components. For this reason, the underside of the coverings approaches closer and closer to the actual chips, which can lead to the mechanical problems described above. In particular in the case of sensitive components with flexible interconnect elements, this can lead to damage to the component.

Such a protective element is generally also used as a heat spreader. Here, the components, located underneath, for example semiconductor components, are coupled mechanically and thermally to a thermally conductive material, the “gap filler” as it is known, on the protective element. A gap filler can contain silicon, for example, and can contain a proportion of metals or metal oxides. As a result, movement of the “heat spreader” is transmitted directly to the components. If the movement of the protective element is too great, damage in the electrical connections can occur and can lead to failure of components. As a result of the often low inherent stiffness of the protective element, protection of the components located underneath against compression in the Z direction (at right angles to the plane of the substrate surface) is additionally likewise not ensured.

### SUMMARY OF THE INVENTION

It is accordingly an object of the invention to provide a protective device for subassemblies that overcomes the above-mentioned disadvantages of the prior art devices and methods of this general type, in which displacement of the covering in the Z direction is prevented or at least reduced to such an extent that damage to the contacts or to the components to be protected can be prevented.

With the foregoing and other objects in view there is provided, in accordance with the invention, in a subassembly having a substrate and a plurality of components disposed on the substrate, a protective device for protecting the components. The protective device contains at least one covering element for covering the subassembly and having a surface facing the components, and at least one compression prevention element disposed between the covering element and the substrate. The compression prevention element is connected to the substrate and the surface of the covering element in such a way that a predefined spacing between the covering element and the components to be protected can be maintained.

The invention is generally based on the idea of providing a compression safeguard that prevents sensitive components from being contacted by the covering element in the event of mechanical action on the latter.

The invention is therefore directed first to a protective device for subassemblies having a substrate and a plurality of components disposed thereon and to be protected. The protective device includes the covering element for covering a subassembly, and the compression prevention element, which is disposed between the covering element and the substrate and which is connected to the substrate and a surface of the covering element which faces the subassembly in such a way that a predefined spacing between covering element and the components to be protected can be maintained or is maintained.

In this case, a subassembly is to be understood to mean an end product of a configuration containing a substrate and one or more components disposed thereon. A substrate can be a circuit board made of polymers in the conventional sense, but also a ceramic or metal support on which the components are placed, for example circuit components such as integrated circuits or passive components such as resistors, coils, etc.

A covering element in the sense of the present invention is, for example, an element known from the prior art and which covers the subassembly in the manner of a cover. The covering element can have one or more substantially planar areas to cover the components. These constitute the main areas of the covering element and, in terms of their function, substantially correspond to the covers known in the prior art. The covering element according to the invention can be prepared from various materials used in the prior art. For example, it is possible to bend or fabricate the covering element from metals such as steel, copper or aluminum sheet, but it is also possible to press, cast or otherwise mold the covering element according to the invention from a polymer.

The components to be protected can be of an extremely wide nature. For example, they can be electromechanical or purely mechanical components. One important area of use for the present invention will, however, be in the area of electronics and semiconductor technology, where integrated circuits having a large number of contacts led to the outside have to be protected. It is therefore preferred in particular for the at least one component to be protected to be a circuit component, in particular a semiconductor component, connected to electrical contacts. Here, a circuit component is to be understood to mean any integrated circuit with contacts, be it a housed or unhoused chip. Passive components can also fall under the term circuit components, if they need protection. In addition, the substrate can have conductor tracks or structures like conductor tracks in order to carry electric currents in the circuit components, if the contacts of the various circuit components are alternatively not directly connected to one another, for example by the use of wire bonds.

In order to fulfill the requirement of the invention to comply with a predefined spacing, the compression prevention element can either be configured in such a way that it is in permanent contact with the surface of the substrate and the surface of the covering element, that is to say even when no pressure is being exerted on the covering element, or the compression prevention element can be dimensioned in such a way that a clearance remains, so that in the event of compression of the covering element, the latter can comply up to a certain extent before the compression prevention element prevents further compression in the direction of the substrate.

The compression prevention element can be fixed to the substrate. It can also be fixed to the covering element or connected to neither of the two elements. In this case, it may additionally be necessary to provide a fixing device that prevents the compression prevention element slipping sideways.

In order to fix the compression prevention element, various techniques can be used. It may be preferred for the at least one compression prevention element to be connected to the at least one covering element and/or the substrate by a metallic connecting area, for example by soldering or welding. The at least one compression prevention element can also be connected to the at least one covering element and/or the substrate by adhesive bonding. Finally, it is possible for an adhesive layer to be disposed between the compression prevention element and covering element and/or between the compression prevention element and substrate and fix the elements to one another.

Alternatively, it is likewise possible for the covering element and the at least one compression prevention element to be configured in one piece, for example for the compression prevention element to be machined from a covering element semi-finished product by milling, or for the covering element and compression prevention element to be produced by injection molding. In order to prevent lateral displacement, that is to say in the X/Y direction, of the covering element over the substrate, guides for preventing lateral movement of the at least one compression prevention element can be disposed on the substrate and/or on that surface of the at least one covering element which faces the compression prevention element and immediately beside the at least one compression prevention element. The side of the compression prevention element on which such guides are necessary results from the type of fixing of the compression prevention element to covering element or substrate. Such guides can be, for example, rail-shaped profiles, between which the compression prevention element can engage, or they can constitute a depression in the substrate or the covering element, into which the compression prevention element can be inserted.

It is likewise possible to combine the above-described types of connection and production with one another in one protective device if more than one compression prevention element is used in the protective device.

The compression prevention element can also be fabricated from an extremely wide range of materials. For example, it is preferred for it to contain a polymer, a metal or a ceramic material or to consist thereof. It is likewise possible to use alloys or mixtures to construct the compression prevention element or to assemble the latter from various parts that consist of the same or different materials.

In addition, numerous possibilities are available for the practical configuration of the compression prevention element according to the invention. For example, it is preferred for the compression prevention element to have a rectangular cross section. This permits a relatively broad supporting surface both on the covering element and on the substrate or a supporting element which may be used, and permit forces to be led through well.

In such cases, the compression prevention element can be configured, for example, as an elongate web-like element, which extends linearly over a specific area of the substrate. In such cases, a typical form may be a square profile (in a side view, that is to say parallel to the plane of the substrate). The compression prevention element can also be configured as a cylindrical pillar, that is to say to have a substantially cylindrical outline in a plan view of the compression prevention element and the substrate. Of course, this can be coupled with a rectangular cross section in side view. In this case, a cylindrical outline includes such configurations as circular and elliptical cylinders, oval or four-cornered forms configured with rounded corners, or triangles, rectangles or polygons, if the compression prevention element is viewed from above, that is to say in a view of the substrate.

Depending on the surface of the substrate and of the covering element, it will generally not be possible to achieve adequate compression prevention for all semiconductor components of more complex circuits by using only one compression prevention element. It is therefore preferred for a plurality of compression prevention elements to be disposed in such a way that the predefined spacing between the covering element and the at least one semiconductor component can be maintained over the entire surface of the latter. By using general rules of static's and the practical layout of the subassembly, those skilled in the art can define a specific configuration of the plurality of compression prevention elements for a specific subassembly.

In addition, a filler material, the gap filler as it is known, can be disposed between the covering element and at least one of the semiconductor elements. The filler generally contains a polymeric material, in which for example metal or metal oxides can be incorporated and normally serves to dissipate heat from the semiconductor component to the covering element. In those cases when it is fabricated from an appropriate material, the covering element functions as a heat spreader. When such gap fillers are used, it is particularly important that the compression prevention element prevents the covering element moving, since otherwise, because of the direct coupling to a covering element, the covering element would exert a mechanical action on the components to be protected, such as integrated circuits with “ball grid arrays” via the gap filler, even in the case of small movements.

The components that can be protected by the invention may in principle be all components known in the prior art or novel components, if they need appropriate protection, in particular in an X/Y direction, that is to say parallel to the substrate surface. For example, the at least one component can be a housed component or a flip-chip.

In addition, the protective device according to the invention can have fixing elements with which the covering element is fixed to the subassembly, for example to the substrate. The fixing elements can preferably be rivets.

The substrate can have any form known in the prior art. The substrate is preferably a circuit board with contact points to make contact with semiconductor components to be protected. However, it can also be a microcircuit board or a ceramic carrier for corresponding elements. The contact points will normally lie on the circuit board or microcircuit board. However, it is also possible to imagine direct wire connections between different semiconductor components, and the substrate merely serving as a mechanical holder for the various semiconductor components. In this case, the invention is primarily directed to the protection of such wiring elements, since they constitute the most sensitive part of the subassembly to be protected. In particular, the substrate can be a circuit board having conductor tracks and contacts for connection to the at least one semiconductor component.

The invention is further directed to a method, everything stated in relation to the protective device according to the invention also applying to the same extent to the method, so that reference is made to the entire content relating to the protective device. Conversely, all that has been stated in relation to the method also applies to the protective device.

The invention is directed to a method of producing a protective device for subassemblies having a substrate and a plurality of components disposed thereon and to be protected, which has the following steps:

a) providing a subassembly of this type;

b) fitting at least one compression prevention element to the substrate or to a covering element; or

c) providing a covering element having at least one compression prevention element integrated in one piece; and

d) fitting a covering element or the covering element to the subassembly.

The exemplary embodiment described originates from the field of semiconductor technology and the mounting of semiconductor components on substrates, such as circuit boards. It goes without saying that the invention is not restricted to an application in protective measures for semiconductor components, but can also be used for other components to be protected, such as mechanical components. The following example is therefore to be viewed as non-exclusive.

Other features which are considered as characteristic for the invention are set forth in the appended claims.

Although the invention is illustrated and described herein as embodied in a protective device for subassemblies, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

The single FIGURE of the drawing is a diagrammatic, partial, sectional view of a subassembly according to the invention.

### DESCRIPTION OF THE PREFERRED EMBODIMENTS

Referring now to the single FIGURE of the drawing in detail, there is shown a subassembly 2 containing a substrate 3 and semiconductor components 4 which are disposed thereon and which are connected to the substrate 3 via contacts 5 and conductor tracks 13. It goes without saying that other ways of making contact are also possible, for example directly between the individual semiconductor components. Also provided in this example are gap fillers 6, which fill the interspace between the semiconductor components 4 and a covering element 1. Further elements, for example passive components or supporting elements for supporting compression prevention elements, can also be provided on a surface 3a of the substrate 3. Shown in the left-hand area of the figure is a first compression prevention element 7, which is configured integrally with the covering element 1 (i.e. a one-piece unit). The compression prevention element 7 is supported on the surface 3a of the substrate 3. Shown in a central area of the figure is a second compression prevention element 8 which, for example, has been produced from a material that differs from the covering element 1 and/or the substrate 3 and is connected to the elements, for example by welding, soldering, adhesive bonding or screwing. Finally, a third compression prevention element 9 is shown in the right-hand area of the figure, being secured against lateral displacement via a guide 10 on the covering element 1 and via a further guide 11 on the substrate 3. The third compression prevention element 9 can additionally also be fixed to the covering element 1 and/or the substrate 3, it being possible for the fixing to be carried out as in the case of the second compression prevention element 8. Given simultaneous fixing of the compression prevention elements, possible other fixing methods of the covering element 1 on the substrate 3, such as rivets, may be omitted.

As explained, as a result of introducing the compression prevention element between the substrate 3 and the covering element 1, mechanical deformation and movement of the covering element 1 in a Z direction is prevented. As a result of applying such a mechanically stiff compression prevention element 7, 8, 9 between the covering element 1 and the substrate 3, the cover element is prevented from being moved in the Z direction and, as a result, damage to the components is prevented. The fixing of the compression prevention element can in this case be carried out by pressing or adhesion, for example by molding, dispensing, printing, potting, insertion, adhesive bonding, soldering or welding. If the compression prevention element is additionally fixed to the substrate 3 and the covering element 1, then movement in the X/Y direction, that is to say in the plane of the substrate surface, is also prevented.

We claim:

1. In a subassembly having a substrate and a plurality of components disposed on the substrate, a protective device for protecting the components, the protective device comprising
at least one covering element for covering the subassembly and having a surface facing the components; and
at least one compression prevention element disposed between said covering element and the substrate, said compression prevention element connected to the substrate and said surface of said covering element such that a predefined spacing between said covering element and the components to be protected can be maintained.

2. The protective device according to claim 1, wherein the components to be protected are circuit components connected to electrical contacts.

3. The protective device according to claim 1, wherein said compression prevention element is fixed to the substrate.

4. The protective device according to claim 1, wherein said compression prevention element is fixed to said covering element.

5. The protective device according to claim 1, wherein said compression prevention element is connected to at least one of said covering element and the substrate by a metallic connecting area.

6. The protective device according to claim 1, wherein said compression prevention element is connected to at least one of said covering element and the substrate by adhesive bonding.

7. The protective device according to claim 1, further comprising:
a first adhesive layer disposed between and fixing said compression prevention element to said covering element; and
a second adhesive layer disposed between and fixing said compression prevention element to the substrate.

8. The protective device according to claim 1, wherein said covering element and said compression prevention element are a one-piece unit.

9. The protective device according to claim 1, further comprising guides disposed on at least one of the substrate and on said surface of said covering element facing said compression prevention element, said guides further disposed immediately beside said compression prevention element to prevent a lateral movement of said compression prevention element.

10. The protective device according to claim 1, wherein said compression prevention element contains at least one material selected from the group consisting of polymers, metals and ceramic materials.

11. The protective device according to claim 1, wherein said compression prevention element has a rectangular cross section.

12. The protective device according to claim 1, wherein said compression prevention element is cylindrical.

13. The protective device according to claim 1, wherein said compression prevention element is one of a plurality of compression prevention elements disposed such that the predefined spacing between said covering element and the components to be protected can be maintained over an entire surface of the components.

14. The protective device according to claim 2, further comprising a gap filler disposed between said covering element and the components.

15. The protective device according to claim 2, wherein one of the components is a housed component.

16. The protective device according to claim 2, wherein one of the components forms a flip-chip.

17. The protective device according to claim 1, further comprising fixing elements with which said covering element is fixed to the subassembly.

18. The protective device according to claim 17, wherein said fixing elements are rivets.

19. The protective device according to claim 2, wherein the substrate is a circuit board having conductor tracks and contacts for connection to the components.

20. The protective device according to claim 2, wherein the circuit components are semiconductor components.

21. A method for producing a protective device for subassemblies having a substrate and a plurality of components disposed on the substrate and to be protected, which comprises the steps of:
providing a subassembly;
fitting at least one compression prevention element to the substrate; and
fitting a covering element on the subassembly.

22. A method for producing a protective device for subassemblies having a substrate and a plurality of components disposed on the substrate and to be protected, which comprises the steps of:
providing a subassembly;
providing a covering element;
fitting at least one compression prevention element to the covering element; and
fitting the covering element on the subassembly.

23. A method for producing a protective device for subassemblies having a substrate and a plurality of components disposed on the substrate and to be protected, which comprises the steps of:
providing a subassembly;
providing a covering element having at least one compression prevention element integrated thereon in one piece; and
fitting the covering element to the subassembly.
